(19) United States
(12) Patent Application Publication
(10) Pub. No.: US 2007/0232093 A1
(43) Pub. Date: Oct. 4, 2007

(54) METHOD AND ELECTRONIC DEVICE FOR COMMUNICATING WITH EXTERNAL MODULE

(75) Inventor: Wei-Chun Chang, Shulin City (TW)

Correspondence Address: SNELL & WILMER L.L.P.;One Arizona Center, 400 East Van Buren, Phoenix, AZ, 85004-2202, US

(73) Assignee: BENQ CORPORATION, Taoyuan (TW)

(21) Appl. No.: 11/696,396

(22) Filed: Apr. 4, 2007

(30) Foreign Application Priority Data
Apr. 4, 2006 (TW) 095111912

(51) Int. Cl. H05K 1/00

(52) U.S. Cl. 439/75

(57) ABSTRACT

An electronic device and a method for communicating with an external module are disclosed. The electronic device includes a first set of connectors, a second set of connectors and a third set of connectors. A predetermined ID is stored in the electronic device. The method includes the following steps: (a) when the external module is separated from the electronic device, the first set of connectors and the second set of connectors being capable of transmitting a video signal; (b) when the external module is coupled to the electronic device, (b1) the third set of connectors transmits a query signal to the external module, (b2) The third set of connectors receives a response from the external module, and (b3) the second set of connectors supplies a power energy to the external module if the response matches the predetermined ID.

### TECHNICAL FIELD

The present invention relates to an electronic device and method for communicating with an external module, particularly to an electronic device and method for determining whether to supply power energy to the external module by comparing a response to a predetermined ID.

### BACKGROUND OF THE INVENTION

Many kinds of electronic products have been broadly used while various applications are continuously developed nowadays. FIG. 1 illustrates one conventional electronic device and its application. A projector 100 connects to a laptop computer 120 through a connection line 110. The laptop computer 120 transmits video signals to the projector 100 through the connection line 110 and then an image is projected onto the screen 130 by the projector 120. It is commonly used in many situations, such as a presentation, lecture, product demonstration, etc. However, it is a trend to develop the projector 100 smaller and smaller, so that the number of internally embedded signal interfaces is limited. For example, a typical projector may be only equipped with one of a D-Sub terminal, S terminal, and Video line-in. However, there are still various interfaces that the user wishes to place in a typical projector, such as HDTV, Audio line-in, Co-axial cable, Component terminal, infrared remote, Ethernet, etc. The lack of interface options may be inconvenient for a user.

Therefore, one solution is to provide an external module to extend functionalities of the projector 100. In other words, it provides the possibility of flexibly improving the projector with the external module to support the functionalities of video, audio, network, infrared remote, etc. FIG. 2A and FIG. 2B illustrate a conventional method for providing power energy to an external module. Referring to FIG. 2A, the electronic device 200 uses a standard video interface 202, such as D-Sub interface or DVI interface, to communicate video signals with the external module 240. Further, an additional power supply interface 204 is used to supply power energy to the external module 240. In this scheme, the external module 240 needs to be coupled with two interfaces 202 and 204 at the same time. It is not only inconvenient to users, but also increases the size of the external module 240, and thus limits the design flexibility.

In FIG. 2B, the electronic device 200 uses a special video interface 206 to connect to the external module 240. By means of the special video interface 206, the electronic device 200 may simultaneously supply power energy as well as the video signal to the external module 240. However, using the special video interface 206 will reduce the compatibility of the device. Generally, different manufacturers provide their own specialized interfaces; as a result these products may not be interchangeable, which is inconvenient for users.

Therefore, it is advantageous to provide an electronic device and method for communicating with and supplying power energy to an external module through a standard video interface.

### SUMMARY OF THE INVENTION

One aspect of the present invention is to determine whether to supply power energy to an external module by comparing a response to a predetermined ID.

Another aspect of the present invention is to supply power energy and data signals to an external module through a standard transmission interface.

The present invention discloses a method for an electronic device communicating with an external module. The electronic device includes a first set of connectors, a second set of connectors and a third set of connectors. A predetermined ID is stored in the electronic device. The method includes the following steps: (a) when the external module is separated from the electronic device, the first set of connectors and the second set of connectors are capable of transmitting a video signal, (b) when the external module is coupled to the electronic device, (b1) the third set of connectors transmits a query signal to the external module, (b2) the third set of connectors receives a response from the external module, (b3) the second set of connectors supplies a power energy to the external module when the response matches the predetermined ID.

The present invention also discloses a method for an electronic device communicating with an external module. The electronic device has a transmission interface, and the transmission interface has a first set of connectors, a second set of connectors, a third set of connectors and a fourth set of connectors. The external module has an identification circuit and a module circuit. The first set of connectors is capable of transmitting a data signal to the external module. A predetermined ID is stored in the electronic device. The method comprising the steps of: determining if the external module is electrically coupled to the electronic device; if the external module is electrically coupled to the electronic device, the fourth set of connectors supplying a first power energy to the identification circuit of the external module to sustain the operation of the identification circuit of the external module; the third set of connectors transmitting a query signal to the identification circuit of the external module; the third set of connectors receiving a response from the identification circuit of the external module; and the second set of connectors supplying a second power energy to the module circuit of the external module if the response matches the predetermined ID.

The present invention also discloses an electronic device for communicating with an external module. The electronic device includes a first set of connectors, a second set of connectors and a third set of connectors. When the external module is separated from the electronic device, the first set of connectors and the second set of connectors are capable of transmitting a data signal. When the external module is coupled to the electronic device, the third set of connectors transmits a query signal to the external module and receives a response from the external module. The second set of connectors supplies a power energy to the external module if the response matches a predetermined ID.

The present invention also discloses an electronic device for communicating with an external module. The external module has an identification circuit and a module circuit. The electronic device includes a memory and a transmission interface. The memory stores a predetermined ID. The transmission interface is electrically coupled to the external module. The transmission interface includes a first set of connectors, a second set of connectors, a third set of connectors and a fourth set of connectors. The first set of connectors transmits a data signal to the external module. The fourth set of connectors supplies a first power energy to the identification circuit of the external module for sustaining the operation of the external module. The third set of connectors transmits a query signal to the identification circuit of the external module and receives a response from the identification circuit of the external module. The second set of connectors supplies a power energy to the external module if the response matches the predetermined ID.

The electronic device according the present invention may further include a wireless receiver and the external module further includes a wireless connector. The wireless connector transmits an auxiliary signal to the wireless receiver allowing the electronic device to identify the external module.

The electronic device according to the present invention further includes a first engagement sensor, and the external module further includes a second engagement portion. When the second engagement portion engages with the first engagement sensor, the second set of connectors are triggered to supply the second power energy to the external module.

### BRIEF DESCRIPTION OF THE DRAWINGS

FIG. 1 illustrates a conventional electronic device and its application;

FIG. 2A and FIG. 2B illustrate a conventional method for providing power energy to a external module;

FIG. 3 illustrates an electronic device and an external module according to one embodiment of the present invention;

FIG. 4 illustrates an electronic device and an external module according to another embodiment of the present invention;

FIG. 5 further illustrates a transmission interface according to one embodiment of the present invention;

FIG. 6A to FIG. 6E illustrate a circuit according to one embodiment of the present invention; and

FIG. 7 illustrates a flowchart of a method for communicating with an external module according to one embodiment of the present invention.

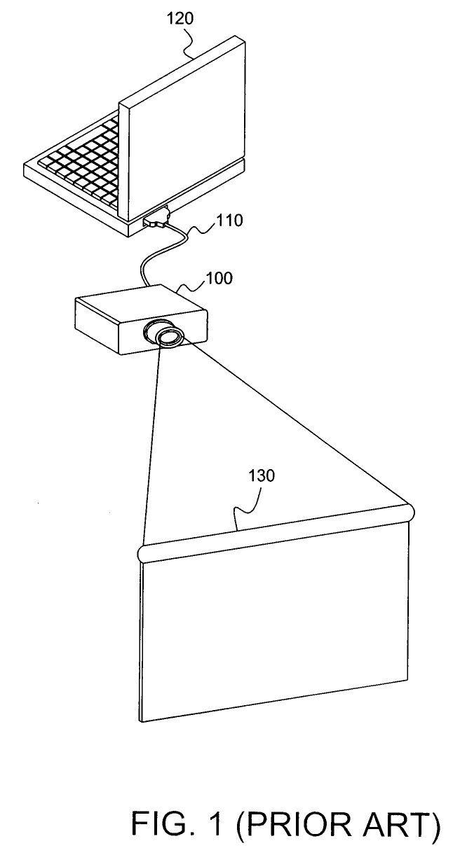

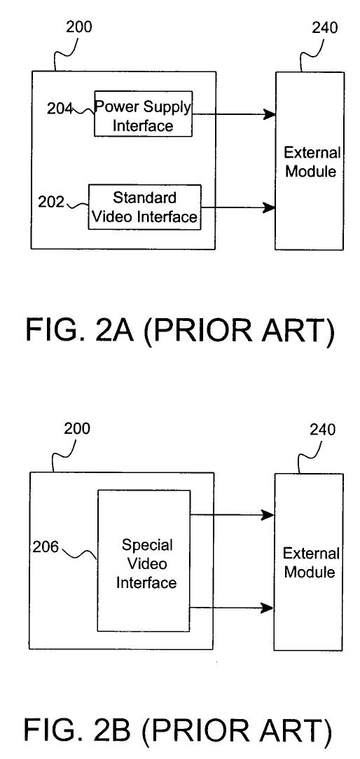

### DETAILED DESCRIPTION OF THE PREFERRED EMBODIMENTS

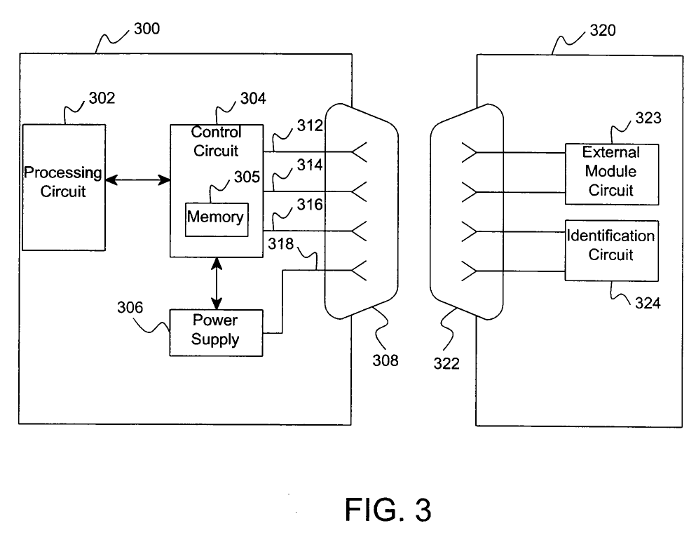

FIG. 3 illustrates an electronic device 300 and an external module 320 according to one embodiment of the present invention. The electronic device 300 has a signal processing circuit 302, a control circuit 304, a memory 305, a power supply 306 and a transmission interface 308. The external module 320 has a module interface 322, an identification circuit 324 and an external module circuit 323. The electronic device 300 communicates with the external module 320 through the transmission interface 308. In this embodiment, the electronic device 300 is a projector, and the external module may be a circuit of audio, video, infrared remote control, or Ethernet adopter. The electronic device 300 transmits/receives such signals to/from another device, such as a laptop, through the external module 320. It is noted that the present invention is not limited to the spcific embodiments, and may be embodied in other devices. In another embodiment, for example, the electronic device 300 may be a LCD display communicating with a wireless base station through the external module 320.

The transmission interface 308 has a first set of connectors 312, a second set of connectors 314, a third set of connectors 316, and a fourth set of connectors 318. In this embodiment, “transmission interface” is a standard video interface, such as a D-sub interface or a DVI interface. The “connector” is the pin in the transmission interface for transmitting and/or receiving signals. Details of the transmission interface 308 will be discussed later. Signal processing circuit 302 processes various kinds of signals, such as projecting the images to the screen, playing the audio signals, or converting the network signals. The control circuit 304 is configured to control and provide the functions described in the present invention. In this embodiment, the memory 305 is disposed inside the control circuit 304. In other embodiments, however, the memory 305 may be disposed outside the control circuit 304. The control circuit 304 retrieves the predetermined ID stored in the memory 305 to identify the external module 320.

As described above, the transmission interface is a standard video interface, so that it provides a high compatibility to a standard connector. When the transmission interface 308 of the electronic device 300 is separated from the external module 320, it may be selectively coupled to a transmission line so that the first set of connectors 312 and/or the second set of connectors 314 transmits and/or receives signals to/from another device through the transmission line.

The module interface 322 of the external module 320 corresponds to the transmission interface 308 of the electronic device 300. For example, the module interface 322 may be a D-Sub connector or a DVI connector. The fourth set of connectors 318 supplies a first power energy to the identification circuit 324 of the external module 320 for sustaining the first operation of the identification circuit 324. Meanwhile, the control circuit 304 transmits a query signal to the identification circuit 324 of the external module 320 through the third set of connectors 316, and receives a response from the identification circuit 324. The control circuit 304 supplies a second power energy to the external module circuit 323 of the external module 320 through the second set of connectors 314 if the response matches the predetermined ID, and transmits a video data signal to the external module circuit 323 through the first set of connectors 312. That is, the external module circuit 323 of the external circuit 320 receives the second power energy to support its operation of communicating with the signal processing circuit 302 of the electronic device 300, such as projecting the images to the screen, playing the audio signals, or converting the network signals.

It is noted that the first power energy through the fourth set of connectors 318 is smaller than the second power energy through the second set of connectors 314. Therefore, the first power energy is provided only for the operation of the identification circuit 324. When the electronic device 300 receives the response from the identification circuit 324 and identifies the external module 320 coupled to the transmission interface 308, the second power energy is then supplied to the external module 320 through the second set of connectors 314. Thus, the second power energy is supplied through the second set of connectors 314 only when the external module 320 coupled to the electronic device 300 is confirmed to be compatible with the second power energy step.

Therefore, when other connector/device other than the external module 320 is coupled to the transmission interface 308, the second set of connectors 314 will not be used to supply the power energy so that the coupled device will not be damaged while the compatibility of the transmission interface 308 to the standard connector may still be preserved. For example, when a standard DVI video connector is coupled to the transmission interface 308, the second set of connectors 314 is used to transmit the standard DVI video signals.

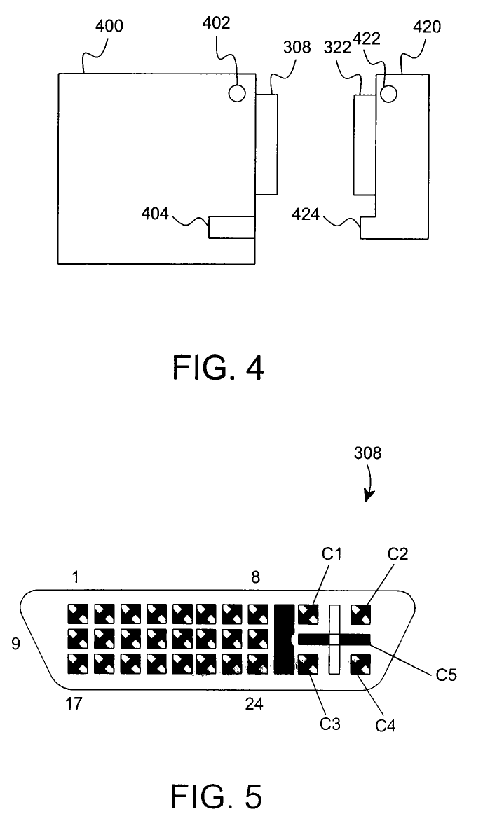

FIG. 4 illustrates an electronic device 400 and an external module 420 according to another embodiment of the present invention. Referring to FIG. 3 and FIG. 4, similar reference numbers denote similar elements, and some description of features which are the same as the above embodiment are omitted below for conciseness. In this embodiment, electronic device 400 further includes a wireless receiver 402 (for infrared or RF signal), and the external module 420 further includes a wireless connector 422. When the external module 420 is coupled to the electronic device 400, a first power energy is supplied to the wireless connector 422 through the fourth set of connectors 318. The wireless connector 422 transmits an auxiliary signal to the wireless receiver 402 allowing the electronic device 400 to identify the external module 420. In other words, the auxiliary signal can be used to further identify the external module 420, in order to make sure the second power energy will not be accidentally supplied to wrong devices resulting in unexpected damages.

Similarly, the electronic device 400 may further include a first engagement sensor 404, and the external module 420 may further include a second engagement portion 424. When the external module 420 is coupled to the electronic device 400, the second engagement portion 424 is engaged with the first engagement sensor 404 to unlock a safety mechanism for allowing the second set of connectors 314 to supply the power energy to the external module 420. The benefit of using the mechanical safety mechanism is to assure that the external module 420 will be correctly identified even if the above-described electronic-type safety mechanism fails. In the present embodiment, the first engagement sensor 404 is a recess and the second engagement portion 424 is a protnision. In other embodiments, however, the first engagement sensor 404 and the second engagement portion 424 may be implemented as other engaging devices, such as hooks, etc.

FIG. 5 further illustrates a transmission interface 308 according to one embodiment of the present invention. In this embodiment, the transmission interface 308 is a DVI-integrated (DVI-I) interface. The DVI-I interface is a transmission interface supporting both analog and digital video signals. DVI-I interface contains 29 pins for transmitting/receiving various signals. The specification of the pins in DVI-I interface is described in the following table:

| Pin | Definition | Pin | Definition | Pin | Definition |
|---|---|---|---|---|---|
| 1 | T.M.D.S. data 2− | 9 | T.M.D.S. data 1− | 17 | T.M.D.S. data 0− |
| 2 | T.M.D.S. data 2+ | 10 | T.M.D.S. data 1+ | 18 | T.M.D.S. data 0+ |
| 3 | T.M.D.S. data 2/4 | 11 | T.M.D.S. data 1/3 | 19 | T.M.D.S. data |
| | | | | | 1 + 0/5 |
| 4 | T.M.D.S. data 4− | 12 | T.M.D.S. data 3− | 20 | T.M.D.S. data 5− |
| 5 | T.M.D.S. data 4+ | 13 | T.M.D.S. data 3+ | 21 | T.M.D.S. data 5+ |
| 6 | DDC clock | 14 | +5 V Power | 22 | T.M.D.S. clock |
| | | | | | Shield |
| 7 | DDC data | 15 | Ground | 23 | T.M.D.S. clock+ |
| 8 | Analog V-Sync | 16 | Hot-Plug detection | 24 | T.M.D.S. clock− |
| C1 | Analog Red | C2 | Analog Green | C3 | Analog Blue |
| C4 | Analog H-Sync | C5 | Analog Ground | | |

DVI-I interface supports the digital signal of TMDS signal (Transition Minimized Differential Signaling) and analog signal. Other details of DVI-I, being a public standard, are omitted here for conciseness.

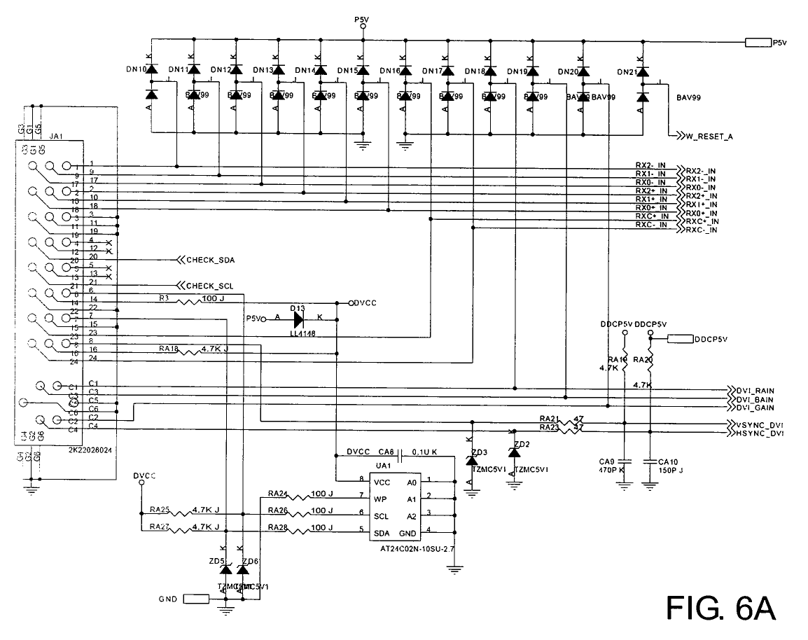

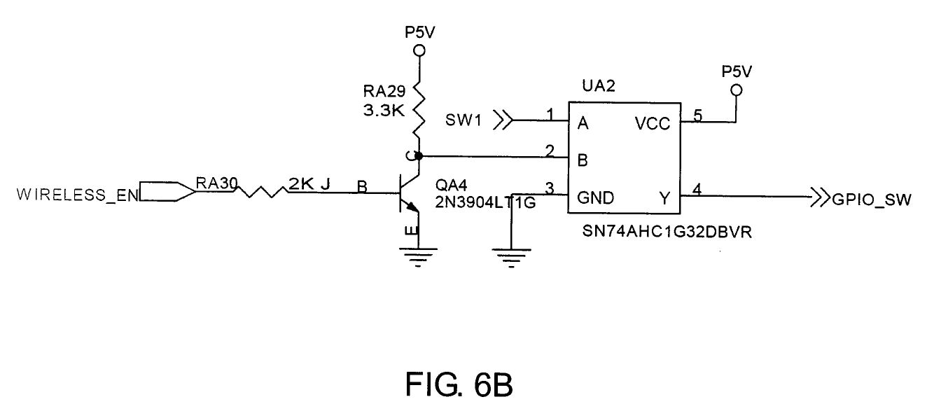

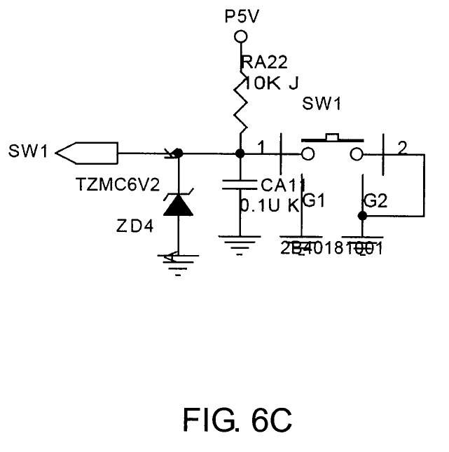

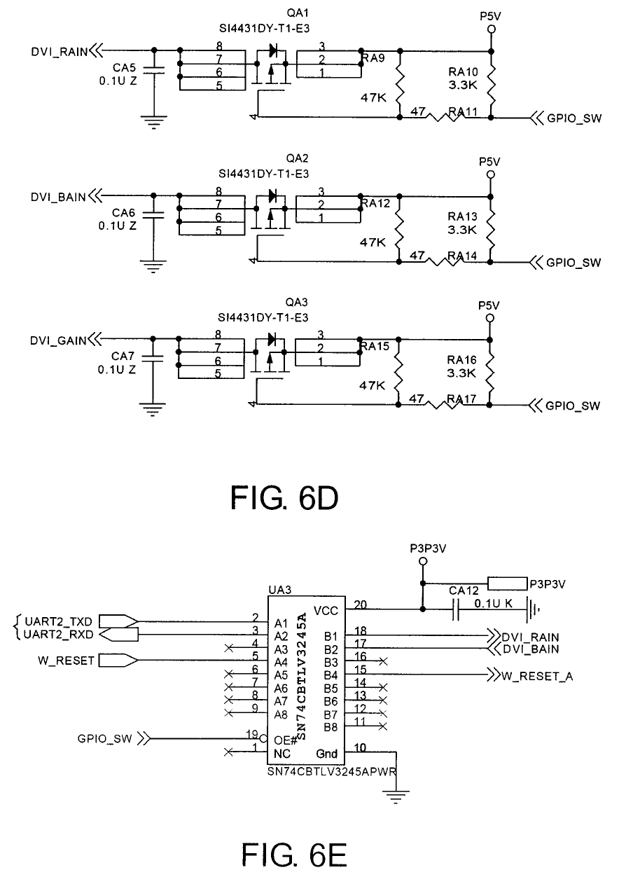

FIG. 6A to FIG. 6E illustrate a circuit applied to DVI-I interface according to one embodiment of the present invention. Referring to FIG. 6A, when the external module 420 is separated from the electronic device 400 or a standard connector is coupled to the electronic device 400, DVI-I interface is operated in a standard mode. That is, the pins C1, C3, and C5 respectively transmit analog video signals, shown as DVI_RAIN, DVI_BAIN, and DVI_GAIN in the drawings.

When the external module 420 is coupled to the transmission interface 308 of the electronic device 400 as described above, the electronic device 400 transmits a 5V DC to the identification circuit 324 through the fourth set of connectors (pin 14=5V, pin 15=GND).

Pins 20 and 21 (the third set of connectors) in the DVI-I interface are configured to receive high definition video signals. In this embodiment, another transmission interface may also be additionally used, such as I2C, RS232, or GPID. Therefore, the control circuit 304 transmits the query signal to the external module 420 through pins 20 and 21, and again the response is received through pins 20 and 21. The control circuit 304 will determine whether the response matches the predetermined ID stored in the memory 305. When they are matched, the control circuit 304 will initiate the WIRELESS_EN signal shown in FIG. 6B.

Referring to FIG. 6C, when the second engagement portion 424 is engaged with the first engagement sensor 404, a safety mechanism is unlocked, such as a switch shown as SWI in the drawing. When both SWI and WIRELESS_EN are initiated, the circuit shown in FIG. 6B will send a GPIO_SW signal. The GPIO_SW signal will initiate the circuit shown in FIG. 6D. Therefore, the electronic device 400 will supply the power energy to the external module 420 through DVI_RAIN, DVI_BAIN, and/or DVI_GAIN (i.e. pins C1, C3, C5, the second set of connectors).

When the electronic device 400 identifies the external module 420 and supplies the power energy, the electronic device 400 uses the circuit shown in FIG. 6E (UART2_TXD and UART2_RXD, first set of connectors) to communicate with the external module 420.

The above-described embodiment is illustrated as exemplary purpose rather than limitations. There are still various modifications and changes to the present invention. For example, the communication between the electronic device 400 and the external module 420 is not limited to specific pins. Instead, any non-used or available pins can be used to transmit signal between them. For example, the pins of Vertical Sync and/or Horizontal Sync may be used to transmit the query signal or receive response.

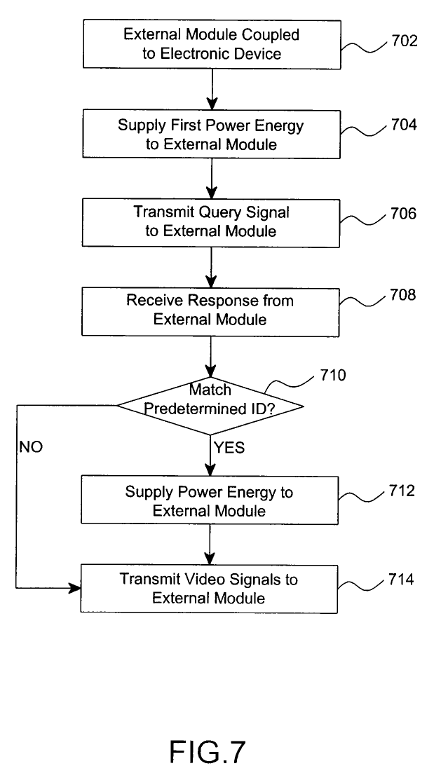

FIG. 7 illustrates a flowchart of a method according to one embodiment of the present invention. In step 702, the external module 420 is coupled to the transmission interface 308 of the electronic device 400. In step 704, the electronic device 400 supplies the first power energy to the external module 420 through the fourth set of connectors. In step 706, the electronic device 400 transmits a query signal to the external module 420 through the third set of connectors. In step 708, the electronic device 400 receives a response from the external module 420. Thereafter, in step 710, a determination is made as to whether the response matches a predetermined ID. If the response does not match the predetermined ID, the electronic device 400 will determine that the coupled device is not the external module 420, and a standard operation mode is used to transmit video signals through the standard pins. If the response matches the predetermined ID, the process proceeds to step 712, and the electronic device 400 supplies the power energy to the external module 420 through the second set of connectors. In step 714, the electronic device 400 transmits video signals to the external module 420 through the first set of connectors.

As set forth in the above descriptions, the present invention provides a method for an electronic device to communicate with an external module using the standard video transmission interface without an additional special transmission interface. The electronic device determines whether to provide power energy by the control circuit with electronic and/or mechanical safety mechanism so as to prevent the external module from being damaged.

The spirit and scope of the present invention can be clearly understood by the above detailed descriptions of the preferred embodiments. The embodiments are not intended to limit the scope of the invention. Contrarily, various modifications of the illustrative embodiments, as well as other embodiments of the invention, will be apparent to persons skilled in the art upon reference to this description. It is therefore contemplated that the appended claims will cover any such modifications or embodiments as falling within the true scope of the invention.

We claim:

1. A method for an electronic device communicating with an external module, the electronic device having a first set of connectors, a second set of connectors and a third set of connectors, a predetermined ID being stored in the electronic device, the method comprising the steps of:
(a) when the external module is separated from the electronic device, the first set of connectors and the second set of connectors being capable of transmitting a data signal;
(b) when the external module is coupled to the electronic device:
(b1) the third set of connectors transmitting a query signal to the external module;
(b2) the third set of connectors receiving a response from the external module; and
(b3) when the response matching the predetermined ID, the second set of connectors supplying a second power energy to the external module so that the external module is capable to operate.

2. The method according to claim 1, wherein the electronic device further comprising a fourth set of connectors, the method further comprising the following steps before the third set of connectors transmitting the query signal:
the fourth set of connectors supplying a first power energy to the external module so that a portion of the external module is capable to generate the response, the first power energy being smaller than the second power energy.

3. The method according to claim 1, wherein the method further comprising the following steps when the response matches the predetermined ID:
the first set of connectors transmitting a data signal to the external module.

4. The method according to claim 1, wherein the electronic device further having a wireless receiver and the external module further having a wireless connector, the method further comprising:
transmitting an auxiliary signal through the wireless connector to the wireless receiver allowing the electronic device to identify the external module.

5. The method according to claim 1, wherein the electronic device further having a first engagement sensor, and the external module further having a second engagement portion, the method further comprising:
when the response matching the predetermined ID and simultaneously the second engagement portion engaging with the first engagement sensor, the first engagement sensor triggering the second set of connectors to supply the second power energy to the external module.

6. A method for an electronic device communicating with an external module, the electronic device having a transmission interface, the transmission interface having a first set of connectors, a second set of connectors, a third set of connectors and a fourth set of connectors, the external module having an identification circuit and a module circuit, the first set of connectors being capable of transmitting a data signal to the external module, a predetermined ID being stored in the electronic device, the method comprising the steps of:
the external module electrically coupling to the electronic device;
the fourth set of connectors supplying a first power energy to the identification circuit of the external module to sustain the operation of the identification circuit of the external module;
the third set of connectors transmitting a query signal to the identification circuit of the external module;
the third set of connectors receiving a response from the identification circuit of the external module; and
when the response matching the predetermined ID, the second set of connectors supplying a second power energy to the module circuit of the external module.

7. The method according to claim 6, wherein the method further comprising the following step:
when the external module is separated from the electronic device, the first set of connectors and the second set of connectors are transmitting a data signal.

8. The method according to claim 6, wherein the method further comprising the following steps when the response matches the predetermined ID:
the first set of connectors transmitting a data signal to the external module.

9. The method according to claim 6, wherein the electronic device further having a
wireless receiver and the external module further having a wireless connector, the method further comprising:
transmitting an auxiliary signal through the wireless connector to the wireless receiver allowing the electronic device to identify the external module.

10. The method according to claim 6, wherein the electronic device further having a first engagement sensor, and the external module further having a second engagement portion, the method further comprising:
when the response matches the predetermined ID and simultaneously the second engagement portion engages with the first engagement sensor, the first engagement sensor triggering the second set of connectors to supply the second power energy to the external module.

11. An electronic device for communicating with an external module, the electronic device storing a predetermined ID, comprising:
a first set of connectors;
a second set of connectors, when the external module is separated from the electronic device, the first set of connectors and the second set of connectors being capable of transmitting a data signal; and
a third set of connectors, when the external module is coupled to the electronic device, for transmitting a query signal to the external module and receiving a response from the external module;
wherein when the response matching the predetermined ID, the second set of connectors supplying a second power energy to the external module, so that the external module capable to operate.

12. The electronic device according to claim 11, further comprising:
a fourth set of connectors, before the third set of connectors transmitting the query signal, configured to supply a first power energy to the external module, so that a portion of the external module is capable to generate the response, the first power energy being lower than the second power energy.

13. The electronic device according to claim 11, wherein the first set of connectors transmitting a data signal to the external module when the response matches the predetermined ID.

14. The electronic device according to claim 11, further comprising a wireless receiver, and the external module further comprising a wireless connector for transmitting an auxiliary signal to the wireless receiver allowing the electronic device to identify the external module.

15. The electronic device according to claim 11, further comprising a first engagement sensor, and the external module further comprising a second engagement portion, wherein when the response matching the predetermined ID and simultaneously the second engagement portion engages with the first engagement sensor, the second set of connectors is triggered to supply a second power energy to the external module.

16. The electronic device according to claim 11, wherein the first set of connectors transmits a digital signal and the second set of connectors transmits an analog signal.

17. The electronic device according to claim 11, wherein the transmission interface is a DVI-I interface, and the first set of connectors transmits a TMDS signal (Transition Minimized Differential Signaling), and the second set of connectors transmits an analog signal.

18. The electronic device according to claim 17, wherein the electronic device transmits the power energy to the external module through analog RGB pins of the second set of connectors, and transmits the query signal through one of a Vertical Sync pin and a Horizontal Sync pin of the third set of connectors.

19. An electronic device for communicating with an external module, the external module having an identification circuit and a module circuit, the electronic device comprising:
a memory for storing a predetermined ID;
a transmission interface for electrically coupling to the external module, the transmission interface including:
a first set of connectors for transmitting a data signal to the external module;
a second set of connectors;
a third set of connectors for transmitting a query signal to the identification circuit of the external module and receiving a response from the identification circuit of the external module; and
a fourth set of connectors for supplying a first power energy to the identification circuit of the external module, so that the external module capable to generate the response;
wherein when the response matching the predetermined ID, the second set of connectors supplying a second power energy to the external module, so that the module circuit capable to operate.

20. The electronic device according to claim 19, wherein when the external module is separated from the electronic device, the first set of connectors and the second set of connectors are capable of transmitting a data signal.

21. The electronic device according to claim 19, further comprising a wireless receiver, and the external module further comprising a wireless connector for transmitting an auxiliary signal to the wireless receiver allowing the electronic device to identify the external module.

22. The electronic device according to claim 19, further comprising a first engagement sensor, and the external module further comprising a second engagement portion, wherein when the response matching the predetermined ID and simultaneously the second engagement portion engages with the first engagement sensor, the first engagement sensor triggering the second set of connectors to supply a second power energy to the module circuit.

23. The electronic device according to claim 19, wherein the first set of connectors transmits a digital signal and the second set of connectors transmits an analog signal.

24. The electronic device according to claim 19, wherein the transmission interface is a DVI-I interface, and the first set of connectors transmits a TMDS signal (Transition Minimized Differential Signaling), and the second set of connectors transmits an analog signal.

25. The electronic device according to claim 24, wherein the electronic device supplies the power energy to the external module through analogue RGB pins of the second set of connectors, and transmits the query signal through one of a Vertical Sync pin and a Horizontal Sync pin of the third set of connectors.
